(19) United States
(12) Patent Application Publication
(10) Pub. No.: US 2024/0105694 A1
(43) Pub. Date: Mar. 28, 2024

(54) SEMICONDUCTOR PACKAGE AND METHOD OF FABRICATING THE SAME

(71) Applicant: Samsung Electronics Co., Ltd., Suwon-si (KR)

(72) Inventors: Jung Hoo YUN, Suwon-si (KR); Jae Moon LIM, Suwon-si (KR)

(73) Assignee: Samsung Electronics Co., Ltd., Suwon-si (KR)

(21) Appl. No.: 18/464,608

(22) Filed: Sep. 11, 2023

(30) Foreign Application Priority Data
Sep. 28, 2022 (KR) 10-2022-0123327

(51) Int. Cl. H01L 25/16; H01L 21/027; H01L 23/00; H01L 23/13; H01L 23/498

(52) U.S. Cl. CPC H01L 25/16; H01L 21/0273; H01L 23/13; H01L 23/49816; H01L 23/49822; H01L 24/11; H01L 24/13; H01L 24/16; H01L 24/17; H01L 24/32; H01L 24/73; H01L 24/81; H01L 2224/11462; H01L 2224/13023; H01L 2224/13564; H01L 2224/1357; H01L 2224/16227; H01L 2224/16265; H01L 2224/1703; H01L 2224/32225; H01L 2224/32265; H01L 2224/73204; H01L 2224/81203; H01L 2924/19041; H01L 2924/19103; H01L 2924/351

(57) ABSTRACT

A semiconductor package includes a semiconductor chip including a first area and a second area around the first area, and a substrate including a second surface, the second surface facing a first surface of the semiconductor chip, a first trench defined on the second surface, and the first trench at least partially overlapping the second area of the semiconductor chip. The semiconductor package includes a bump structure including first bumps on the first area of the semiconductor chip, and second bumps on the second area of the semiconductor chip, the bump structure between the substrate and the semiconductor chip, and a first passive device in the first trench. The second bumps are in contact with the first surface of the semiconductor chip and the first passive device.

### CROSS-REFERENCE TO RELATED APPLICATION

This application claims priority from Korean Patent Application No. 10-2022-0123327 filed on Sep. 28, 2022 in the Korean Intellectual Property Office, and all the benefits accruing therefrom under 35 U.S.C. § 119, the contents of which in its entirety are herein incorporated by reference.

### FIELD

Some example embodiments of the inventive concepts relate to a semiconductor package and/or a method of fabricating the same.

### BACKGROUND

A semiconductor package may include a substrate and a semiconductor chip, which is stacked on the substrate. The substrate and the semiconductor chip may be electrically connected via a connecting structure including conductive bumps and pads.

However, the reliability of the semiconductor package may be lowered in the process of mounting the semiconductor chip on the substrate, due to the difference in coefficient of thermal expansion (CTE) between the semiconductor chip and the substrate.

### SUMMARY

Some aspects of the inventive concepts provide a semiconductor package with an improved reliability.

Some aspects of the inventive concepts provide a method of fabricating a semiconductor package with an improved reliability.

However, aspects of the inventive concepts are not restricted to those set forth herein. The above and other aspects of the inventive concepts will become more apparent to one of ordinary skill in the art by referencing the detailed description of the inventive concepts given below.

According to an aspect of the inventive concepts, a semiconductor package includes a semiconductor chip including a first area and a second area around the first area, and a substrate including a second surface, the second surface facing a first surface of the semiconductor chip, a first trench defined on the second surface, and the first trench at least partially overlapping the second area of the semiconductor chip. The semiconductor package includes a bump structure including first bumps on the first area of the semiconductor chip, and second bumps on the second area of the semiconductor chip, the bump structure between the substrate and the semiconductor chip, and a first passive device in the first trench, wherein the second bumps are in contact with the first surface of the semiconductor chip and the first passive device.

According to another aspect of the inventive concepts, a semiconductor package comprising a semiconductor chip includes a first area and a second area, the second area around the first area in a plan view of the semiconductor chip, and a substrate including a top surface, the top surface facing a bottom surface of the semiconductor chip, a trench defined in the top surface, and the trench at least partially overlapping the second area of the semiconductor chip. The semiconductor package includes a bump structure including connection bumps in the first area of the semiconductor chip, and dummy bumps on the second area of the semiconductor chip, the bump structure between the substrate and the semiconductor chip, and a passive device in the trench, the passive device between the bump structure and the substrate. A thickness of the dummy bumps differs from a thickness of the connection bumps, the dummy bumps are in contact with the passive device, and the connection bumps are in contact with the substrate.

According to another aspect of the inventive concepts, a method of fabricating a semiconductor package includes providing a semiconductor chip including a first area and a second area, a first semiconductor chip pad in the first area, and a second semiconductor chip pad in the second area, forming photoresist on a bottom surface of the semiconductor chip, the photoresist including an opening which exposes the first semiconductor chip pad, forming first and second metal material layers in the opening, removing the photoresist, providing a substrate including a trench, the trench including a bottom surface which exposes at least one wiring layer, forming a passive device in the trench, the passive device including a bottom surface that faces the bottom surface of the trench, forming a third metal material layer on the wiring layer and a fourth metal material layer on a top surface of the passive device, arranging the substrate and the semiconductor chip where the top surface of the substrate faces the bottom surface of the semiconductor chip, bonding the second metal material layer and the third metal material layer, and bonding the second semiconductor chip pad and the fourth metal material layer.

Effects of the inventive concepts are not limited to those described above, and other effects of the inventive concepts will be apparent from the following description.

### BRIEF DESCRIPTION OF THE DRAWINGS

The above and other aspects and features of the inventive concepts will become more apparent by describing in detail example embodiments thereof with reference to the attached drawings, in which:

FIG. 1 is a layout view of a semiconductor package according to some example embodiments of the inventive concepts;

FIG. 2 is a cross-sectional view taken along line I-I′ of FIG. 1;

FIG. 3 is an enlarged layout view of a region R1 of FIG. 2;

FIG. 4 is a cross-sectional view, taken along line I-I′ of FIG. 1, of a semiconductor package according to some example embodiments of the inventive concepts;

FIG. 5 is an enlarged cross-sectional view of a region R2 of FIG. 4;

FIG. 6 is a layout view of a semiconductor package according to some example embodiments of the inventive concepts;

FIG. 7 is a cross-sectional view taken along line II-IF of FIG. 6; and

FIGS. 8, 9, 10, 11, 12, 13, 14, 15 and 16 are cross-sectional views illustrating a method of fabricating a semiconductor package according to some example embodiments of the inventive concepts.

### DETAILED DESCRIPTION

Some example embodiments of the inventive concepts will be described with reference to the attached drawings. Like reference numerals indicate like elements through the example embodiments, and thus, redundant descriptions thereof will be omitted.

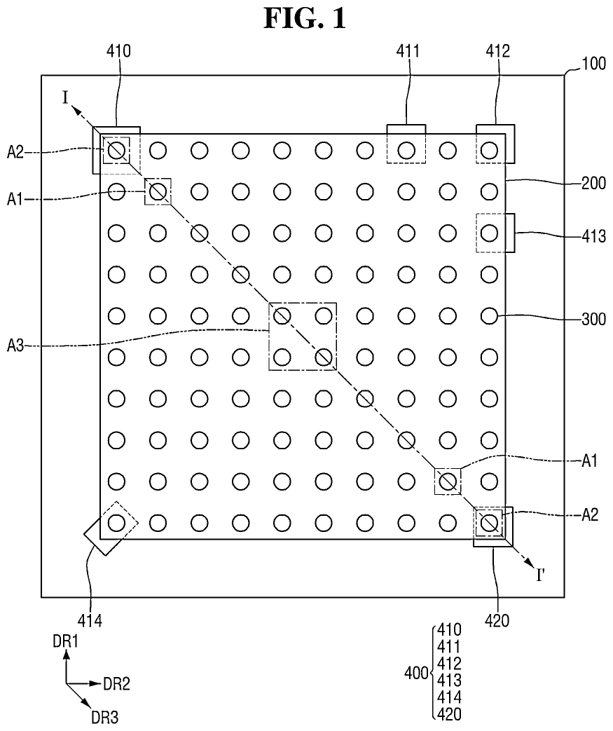

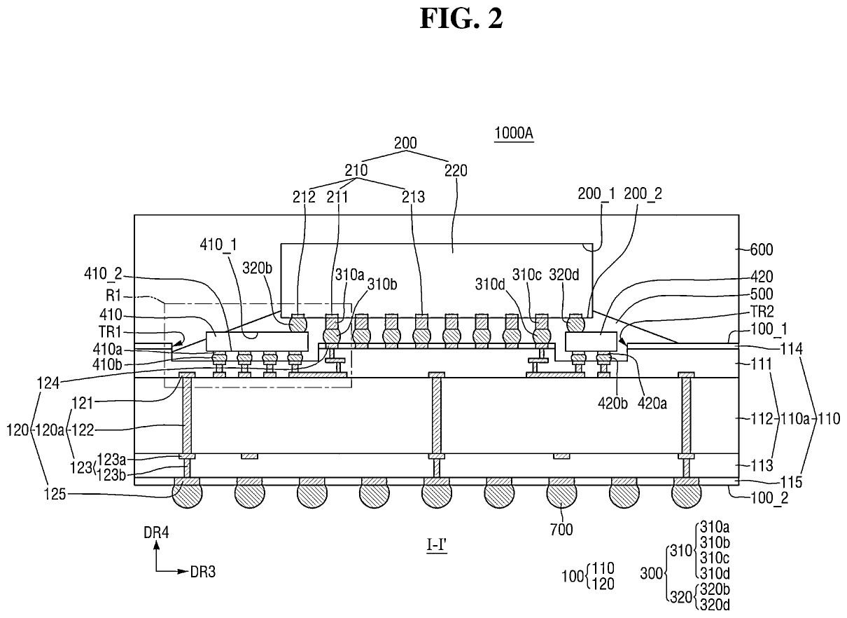

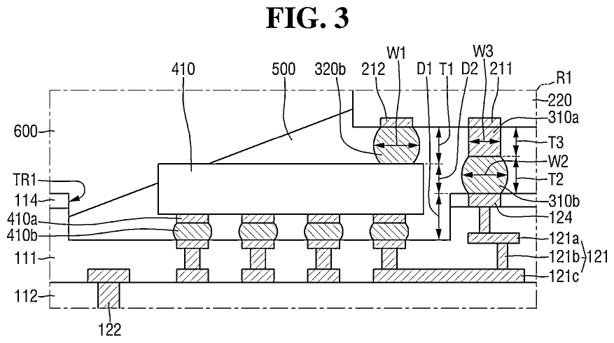

FIG. 1 is a layout view of a semiconductor package according to some example embodiments of the inventive concepts. FIG. 2 is a cross-sectional view taken along line I-I′ of FIG. 1. FIG. 3 is an enlarged layout view of a region R1 of FIG. 2.

Referring to FIGS. 1 and 2, a semiconductor package 1000A may include a substrate 100, a semiconductor chip 200, a bump structure 300, passive devices 400, an underfill material 500, a mold layer 600, and external connection terminals 700.

The substrate 100 may include an insulating structure 110 and a wiring structure 120 in the insulating structure 110.

The insulating structure 110 may include an insulating layer 110a and first and second solder resist layers 114 and 115 on the insulating layer 110a. The wiring structure 120 may include a wiring layer 120a and first connection pads 124 and second connection pads 125 on the wiring layer 120a.

The substrate 100 may have a top surface 100_1 and a bottom surface 100_2, which are opposite to each other. The top surface 100_1 of the substrate 100 may extend in first and second directions DR1 and DR2, which are orthogonal to each other. The top surface 100_1 of the substrate 100 may also extend in a third direction DR3, which diagonally intersects the first and second directions DR1 and DR2. The bump structure 300 may be stacked on the top surface 100_1 of the substrate 100 in a fourth direction DR4 (e.g., a vertical direction), which are orthogonal to the first and second directions DR1 and DR2.

A plurality of external connection terminals 700 may be disposed on the bottom surface 100_2 of the substrate 100. The wiring structure 120 may electrically connect the semiconductor chip 200 and the external connection terminals 700.

The insulating layer 110a may include first, second, and third insulating layers 111, 112, and 113. The first and third insulating layers 111 and 113 may be disposed above and below, respectively, the second insulating layer 112.

The substrate 100 may include, for example, a printed circuit board (PCB) or a ceramic substrate, but the example embodiments are not limited thereto.

The insulating layer 110a may be formed of at least one material selected from among a phenolic resin, an epoxy resin, and polyimide, such as when the substrate 100 includes a PCB. For example, the insulating layer 110a may include at least one material selected from among Ajinomoto Build-up Film (ABF), a composite material composed of woven fiberglass cloth with an epoxy resin binder that is flame resistant (FR-4), tetrafunctional epoxy, polyphenylene ether, epoxy/polyphenylene oxide, bismaleimide triazine (BT), Thermount, cyanate ester, polyimide, and liquid crystal polymer, but example embodiments are not limited thereto.

First and second solder resist layers 114 and 115 may be disposed above and below, respectively, the insulating layer 110a. The first and second solder resist layers 114 and 115 may include, for example, a photo-imageable dielectric (PID) material, but the example embodiments are not limited thereto.

FIG. 2 illustrates that the insulating layer 110a includes three layers, but the example embodiments are not limited thereto. The insulating layer 110a may include a plurality of layers, which may be more or less than the three layers illustrated in the example embodiment of FIG. 2.

The wiring layer 120a may include a plurality of layers. The wiring layer 120a may include first, second, and third wiring layers 121, 122, and 123. The first and third wiring layers 121 and 123 may be disposed above and below, respectively, the second wiring layer 122.

The first wiring layer 121 may be disposed in the first insulating layer 111. The second wiring layer 122 may be disposed in the second insulating layer 112. The first wiring layer 121 may include first wiring pads 121a and second wiring pads 121c, which are electrically connected to the first connection pads 124. The first wiring layer 121 may further include wiring vias 121b, which connect the first wiring pads 121a and the second wiring pads 121c.

The second wiring layer 122 may electrically connect the first and third wiring layers 111 and 113. The second wiring layer 122 may be formed as vias penetrating at least part of the second insulating layer 122, but the example embodiments are not limited thereto.

The third wiring layer 123 may be disposed in the third insulating layer 113. The third wiring layer 123 may include pads 123a and vias 123b, which electrically connect the substrate 100 and the external connection terminals 700.

The wiring structure 120 may include, for example, a conductive material. For example, the wiring structure 120 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or an alloy of the at least one metal, but example embodiments are not limited thereto.

The semiconductor chip 200 may be disposed on the substrate 100. The semiconductor chip 200 may include a device layer 220 and semiconductor chip pads 210.

Referring to FIG. 1, in a plan view, the semiconductor chip 200 may include first, second, and third areas A1, A2, and A3. The third area A3 may be disposed in an innermost part of the semiconductor chip 200 and may correspond to the middle of the semiconductor chip 200. The second area A2 may be disposed on the outside of the third area A3 and may correspond to a periphery part of the semiconductor chip 200. The first area A1 may be part of the semiconductor chip 200 between the second and third areas A2 and A3.

The semiconductor chip pads 210 may include first semiconductor chip pads 211, second semiconductor chip pads 212, and third semiconductor chip pads 213, which correspond to the first, second, and third areas A1, A2, and A3, respectively.

The semiconductor chip 200 may have a top surface 200_1 and a bottom surface 200_2, which are opposite to each other. The semiconductor chip 200 may be mounted on the substrate 100 via flip chip bonding. The bottom surface 200_2 of the semiconductor chip 200 may face the substrate 100 and may refer to an active surface electrically connected to the substrate 100.

Although not specifically illustrated, a passivation layer exposing the semiconductor chip pads 210 may be disposed on the bottom surface 200_2 of the semiconductor chip 200. The semiconductor chip pads 210, which are exposed by the passivation layer, may electrically connect the substrate 100 and the semiconductor chip 200.

The top surface 100_1 of the substrate 100 may face the bottom surface 200_2 of the semiconductor chip 200. A first trench TR1, which overlaps at least partially with the second area A2 of the semiconductor chip 200 in the fourth direction DR4, may be formed on the top surface 100_1 of the substrate 100.

The bump structure 300 may be disposed between the substrate 100 and the semiconductor chip 200 and may connect the substrate 100 and the semiconductor chip 200. For example, the bump structure 300 may be used to bond the substrate 100 and the semiconductor chip 200 via thermal compression bonding, but the example embodiments are not limited thereto.

Referring to FIG. 2, the bump structure 300 may include first bumps 310 and second bumps 320. The first bumps 310 may be disposed on the first area A1 of the semiconductor chip 200, and the second bumps 320 may be disposed on the second area A2 of the semiconductor chip 200.

Each of the first bumps 310 may include a (1_1)-th upper pillar layer 310a, which is disposed on the bottom surface 200_2 of the semiconductor chip 200, and a (1_1)-th upper solder layer 310b, which is disposed between the (1_1)-th upper pillar layer 310 and the top surface 100_1 of the substrate 100.

Each of the second bumps 320 may include a (2_1)-th upper solder layer 320b, which is disposed on the bottom surface 200_2 of the semiconductor chip 200.

Referring to FIG. 1, the passive devices 400 may include a plurality of passive devices (410, 411, 412, 413, 414, and 420). The passive devices (410, 411, 412, 413, 414, and 420) may be disposed in edge areas of the semiconductor chip 200. The passive devices (410, 411, 412, 413, 414, and 420) may have different sizes or shapes. In some example embodiments, the passive devices (410, 411, 412, 413, 414, and 420) may be used as alignment or identification patterns during the fabrication of the semiconductor package 1000A.

A first passive device 410 may have a top surface 410_1 and a bottom surface 410_2, which are opposite to each other. The second bumps 320 may be in contact with the top surface 410_1 of the first passive device 410 and the bottom surface 200_2 of the semiconductor chip 200. The first bumps 310 may not be in contact with the top surface 410_1 of the first passive device 410.

Referring to FIG. 3, the first passive device 410 may be formed in the first trench TR1, which has a first depth D1 from the top surface 100_1 of the substrate 100. The top surface 410_1 of the first passive device 410 may protrude from the top surface 100_1 of the substrate 100 by as much as a second height D2. For example, the first depth D1 of the first trench TR1 may be substantially the same as the second height D2, to which the first passive device 410 protrudes from the substrate 100, but the example embodiments are not limited thereto.

The (2_1)-th upper solder layer 320b may be disposed between the top surface 410_1 of the first passive device 410 and the bottom surface 200_2 of the semiconductor chip 200. The (1_1)-th upper pillar layer 310a and the (1_1)-th upper solder layer 310b may be disposed between the top surface 100_1 of the substrate 100 and the bottom surface 200_2 of the semiconductor chip 200.

The thickness, in the fourth direction DR4, of the second bumps 320 may differ from the thickness, in the fourth direction DR4, of the first bumps 310. Specifically, a thickness T1 of the (2_1)-th upper solder layer 320b may differ from the sum of a thickness T2 of the (1_1)-th upper solder layer 310b and a thickness T3 of the (1_1)-th upper pillar layer 310a. In some example embodiments, the thickness T1 of the (2_1)-th upper solder layer 320b may be less than the sum of the thickness T2 of the (1_1)-th upper solder layer 310b and the thickness T3 of the (1_1)-th upper pillar layer 310a.

A width W1, in the third direction DR3, of the (2_1)-th upper solder layer 320b may differ from a width W2, in the third direction DR3, of the (1_1)-th upper solder layer 310b. For example, the width W1 of the (2_1)-th upper solder layer 320b may be greater than the width W2 of the (1_1)-th upper solder layer 310b. Although not specifically illustrated, the width, in the first or second direction DR1 or DR2, of the (2_1)-th upper solder layer 320b may be greater than the width, in the first or second direction DR1 or DR2, of the (1_1)-th upper solder layer 310b.

A width W3, in the third direction DR3, of the (1_1)-th upper pillar layer 310a may differ from the width W2, in the third direction DR3, of the (1_1)-th upper solder layer 310b. For example, the width W3 of the (1_1)-th upper pillar layer 310a may be less than the width W2 of the (1_1)-th upper solder layer 310b. In some example embodiments, the width W3 of the (1_1)-th upper pillar layer 310a may also be less than the width W1 of the (2_1)-th upper solder layer 320b. Although not specifically illustrated, the width, in the first or second direction DR1 or DR2, of the (1_1)-th upper pillar layer 310a may be less than the width, in the first or second direction DR1 or DR2, of the (1_1)-th upper solder layer 310b and the width, in the first or second direction DR1 or DR2, of the (2_1)-th upper solder layer 320b.

The first passive device 410 may be disposed on the substrate 100 via the (1_1)-th lower pillar layer 410a and the (1_1)-th lower solder layer 410b, which are disposed between the bottom surface 410_2 of the first passive device 410 and the substrate 100 to be apart. In some example embodiments, the first passive device 410 may be a silicon capacitor, but the first passive device 410 may have other suitable types in other example embodiments.

The first passive device 410 and the semiconductor chip 200 may be electrically connected through the first bumps 310 and the wiring layer 120a. Specifically, the first passive device 410 and the semiconductor chip 200 may be electrically connected through the first bumps 310, the first pads 124, the first wiring pads 121a, the wiring vias 121b, the second wiring pads 121c, the (1_1)-th lower pillar layer 410a, and the (1_1)-th lower solder layer 410b. In some example embodiments, the first bumps 310 may be referred to as connection bumps.

However, the first passive device 410 and the semiconductor chip 200 may not be electrically connected through the second bumps 320. In some example embodiments, the second bumps 320 may be referred to as dummy bumps.

The (1_1)-th upper pillar layer 310a and the (1_1)-th lower pillar layer 410a may have, for example, a pillar shape, but the example embodiments are not limited thereto. The (1_1)-th upper pillar layer 310a and the (1_1)-th lower pillar layer 410a may include, for example, Cu, a Cu alloy, Ni, Pd, Pt, Au, cobalt (Co), or a combination thereof, but the example embodiments are not limited thereto.

The (1_1)-th solder layer 310b, the (2_1)-th solder layer 320b, and the (1_1)-th lower solder layer 410b may have, for example, a spherical shape or an elliptical spherical shape, but the example embodiments are not limited thereto. The (1_1)-th solder layer 310b, the (2_1)-th solder layer 320b, and the (1_1)-th lower solder layer 410b may include, for example, Sn, In, bismuth (Bi), antimony (Sb), Cu, Ag, Zn, Pb, or a combination thereof, but the example embodiments are not limited thereto.

Referring to FIGS. 1 and 2, the second passive device 420 may have a different size from the first passive device 410. Specifically, at least one of the lengths, in the first, second, and third directions DR1, DR2, and DR3, of the second passive device 420, may be less than at least one of the lengths, in the first, second, and third directions DR1, DR2, and DR3, of the first passive device 410. Alternatively to what is illustrated in FIG. 2, side surfaces of the semiconductor chip 200 and the second passive device 420 may be aligned with each other, but the example embodiments are not limited thereto.

The second passive device 420 may be substantially the same as the first passive device 410, except for its size, and thus, the above description of the first passive device 410 may be directly applicable to the second passive device 420.

The second passive device 420 may be formed in a second trench TR2, which has the first depth D1 from the top surface 100_1 of the substrate 100. The second trench TR2 may overlap at least partially with the second area A2 of the semiconductor chip 200 in the fourth direction DR4. The top surface of the second passive device 420 may protrude from the top surface 100_1 of the substrate 100 by as much as the second height D2.

Each of the first bumps 310 may further include a (1_2)-th upper pillar layer 310c, which is disposed on the bottom surface 200_2 of the semiconductor chip 200, and a (1_2)-th upper solder layer 310d, which is disposed between the (1_2)-th upper pillar layer 310c and the top surface 100_1 of the substrate 100.

Each of the second bumps 320 may further include a (2_2)-th upper solder layer 320d, which is disposed on the bottom surface 200_2 of the semiconductor chip 200.

The (2_2)-th upper solder layer 320d may be disposed between the top surface of the second passive device 420 and the bottom surface 200_2 of the semiconductor chip 200. The (1_2)-th upper solder layer 310d may be disposed between the top surface 100_1 of the substrate 100 and the bottom surface 200_2 of the semiconductor chip 200.

The thickness, in the fourth direction DR4, of the (2_2)-th upper solder layer 320d may differ from the thicknesses, in the fourth direction DR4, of the (1_2)-th upper solder layer 310d and the (1_2)-th upper pillar layer 310c. In some example embodiments, the thickness, in the fourth direction DR4, of the (2_2)-th upper solder layer 320d may be less than the sum of the thicknesses, in the fourth direction DR4, of the (1_2)-th upper solder layer 310d and the (1_2)-th upper pillar layer 310c.

The width, in the third direction DR3, of the (2_2)-th upper solder layer 320d may differ from the width, in the third direction DR3, of the (1_2)-th upper solder layer 310d. For example, the width, in the third direction DR3, of the (2_2)-th upper solder layer 320d may be greater than the width, in the third direction DR3, of the (1_2)-th upper solder layer 310d. Although not specifically illustrated, the width, in the first or second direction DR1 or DR2, of the (2_2)-th upper solder layer 320d may be greater than the width, in the first or second direction DR1 or DR2, of the (1_2)-th upper solder layer 310d.

The width, in the third direction DR3, of the (1_2)-th upper pillar layer 310c may differ from the width, in the third direction DR3, of the (1_2)-th upper solder layer 310d. For example, the width, in the third direction DR3, of the (1_2)-th upper pillar layer 310c may be less than the width, in the third direction DR3, of the (1_2)-th upper solder layer 310d. In some example embodiments, the width of the (1_2)-th upper pillar layer 310c may be less than the width of the (2_2)-th upper solder layer 320d. Although not specifically illustrated, the width, in the first or second direction DR1 or DR2, of the (1_2)-th upper pillar layer 310c may be less than the width, in the first or second direction DR1 or DR2, of the (1_2)-th upper solder layer 310d and the width, in the first or second direction DR1 or DR2, of the (2_2)-th upper solder layer 320d.

The second passive device 420 may be disposed on the substrate 100 through the (1_2)-th lower pillar layer 420a and the (1_2)-th lower solder layer 420b, which are disposed between the bottom surface of the second passive device 420 and the substrate 100 to be apart. In some example embodiments, the second passive device 420 may be a silicon capacitor, other suitable types of the second passive device 420 may be used in other example embodiments.

The second passive device 420 and the semiconductor chip 200 may be electrically connected through the first bumps 310 and the wiring layer 120a. Specifically, the second passive device 420 and the semiconductor chip 200 may be electrically connected through the first bumps 310, the first pads 124, the first wiring pads 121a, the wiring vias 121b, the second wiring pads 121c, the (1_2)-th lower pillar layer 420a, and the (1_2)-th lower solder layer 420b. In some example embodiments, the first bumps 310 may be referred as connection bumps.

However, the second passive device 420 and the semiconductor chip 200 may not be electrically connected through the second bumps 320. In some example embodiments, the second bumps 320 may be referred to as dummy bumps.

The underfill material 500 may be formed on the substrate 100. The underfill material 500 may be disposed between the semiconductor chip 200 and the substrate 100 and may fill at least parts of the first and second trenches TR1 and TR2. The underfill material 500 may inhibit or prevent breakage of the semiconductor chip 200 by fixing the semiconductor chip 200 onto the substrate 100. The underfill material 500 may cover the bump structure 300. The bump structure 300 may electrically connect the substrate 100 and the semiconductor chip 200, penetrating the underfill material 500.

The underfill material 500 may include, for example, an insulating polymer material such as an epoxy molding compound (EMC), but the example embodiments are not limited thereto. In some example embodiments, the underfill material 500 may include a different material from the mold layer 600. For example, the underfill material 500 may include an insulating material having a better fluidity than the mold layer 600. Accordingly, the underfill material 500 can efficiently fill the narrow space between the substrate 100 and the semiconductor chip 200.

The mold layer 600 may cover the top surface 200_1, parts of the side surfaces of the semiconductor chip 200, and at least parts of the first and second passive devices 410 and 420. The mold layer 600 may fill at least parts of the first and second trenches TR1 and TR2 where the underfill material 500 is not formed.

The mold layer 600 may include, for example, an insulating material such as an EMC. The mold layer 600 may include a thermosetting resin such as an epoxy resin, a thermoplastic resin such as polyimide, or a thermosetting or thermoplastic resin (e.g., ABF, FR-4, or a BT resin) including a reinforcing material such as a filler, but example embodiments are not limited thereto.

The filler material may include at least one selected from the group consisting of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃), but example embodiments are not limited thereto.

The external connection terminals 700 may electrically connect the substrate 200 to an external device. Accordingly, the external connection terminals 700 may provide electrical signals to the substrate 200 and may provide electrical signals from the substrate 200 to an external device.

The external connection terminals 700 may have, for example, a spherical shape or an elliptical spherical shape, but the example embodiments are not limited thereto. The external connection terminals 700 may include, for example, at least one of Sn, In, Pb, Zn, Ni, Au, Ag, Cu, Sb, Bi, and a combination thereof, but the example embodiments are not limited thereto.

According to some example embodiments, passive devices can be disposed on the periphery of a semiconductor chip. In some example embodiments, stress that may be caused by the difference in CTE between a substrate and the semiconductor chip can be further reduced via bumps between the semiconductor chip and the passive devices.

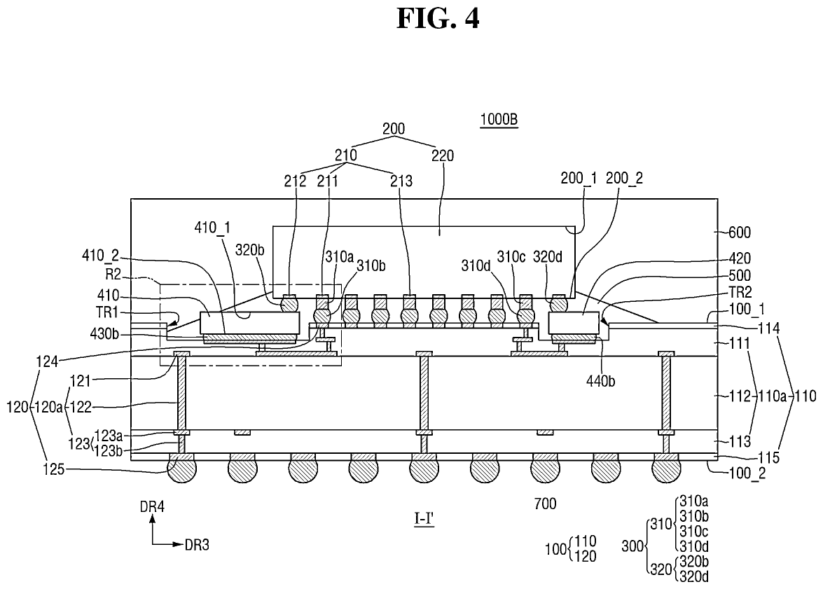

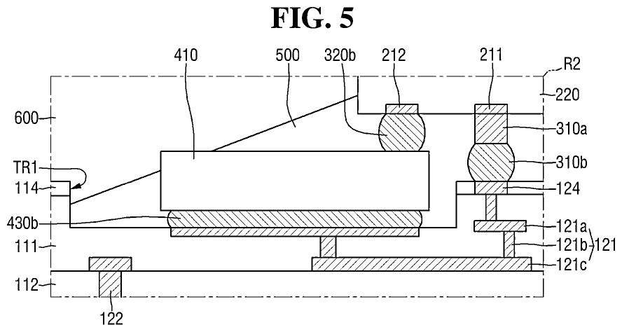

FIG. 4 is a cross-sectional view, taken along line I-I′ of FIG. 1, of a semiconductor package according to some example embodiments of the inventive concepts. FIG. 5 is an enlarged cross-sectional view of a region R2 of FIG. 4. The example embodiment of FIGS. 4 and 5 will hereinafter be described, focusing mainly on the differences with the embodiment of FIGS. 1 through 3.

Referring to FIGS. 4 and 5, a semiconductor package 1000B may include a (1_3)-th lower solder layer 430b and a (1_4)-th lower solder layer 440b. A first passive device 410 may be disposed on a substrate 100 through the (1_3)-th lower solder layer 430b, which is disposed between a bottom surface 410_1 of the first passive device 410 and the substrate 100. A second passive device 420 may be disposed on the substrate 100 through the (1_4)-th lower solder layer 440b, which is disposed between the bottom surface of the second passive device 420 and the substrate 100.

In some example embodiments, the first and second passive devices 410 and 420 may be multilayer ceramic capacitors (MLCCs). However, other example embodiments may include other suitable types of the first and second passive devices 410 and 420.

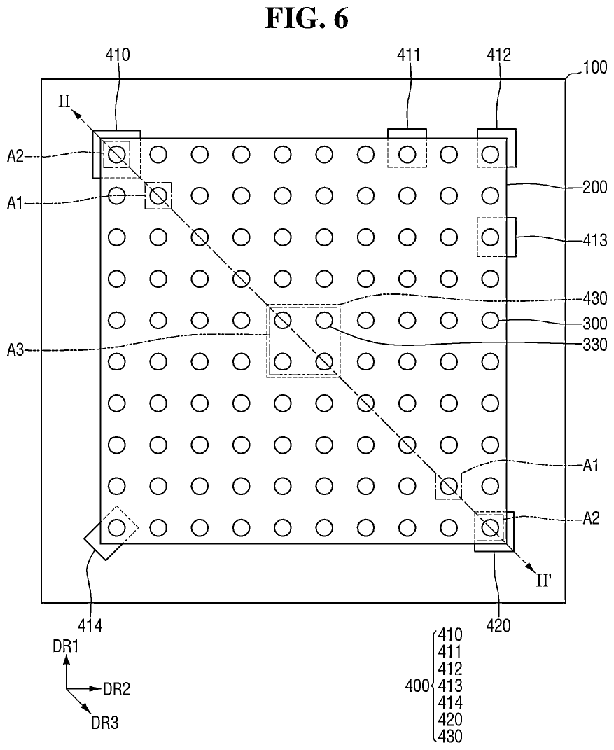

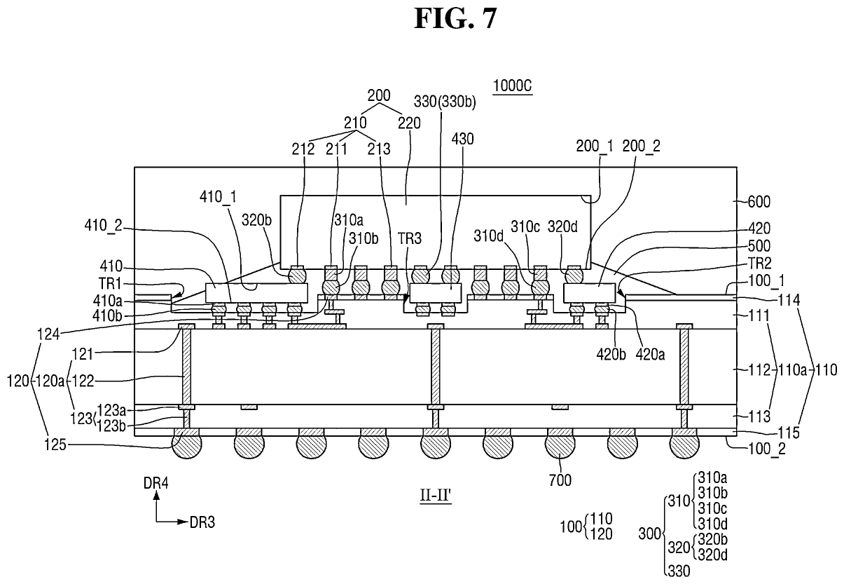

FIG. 6 is a layout view of a semiconductor package according to some example embodiments of the inventive concepts. FIG. 7 is a cross-sectional view taken along line II-II′ of FIG. 6. The example embodiment of FIGS. 6 and 7 will hereinafter be described, focusing mainly on the differences with the example embodiment of FIGS. 1 through 3.

Referring to FIGS. 6 and 7, a semiconductor package 1000C may further include a third trench TR3, which overlaps with a third area A3 of a semiconductor chip 200.

A bump structure 300 may further include third bumps 330, which are disposed on the third area A3 of the semiconductor chip 200, between a substrate 100 and the semiconductor chip 200.

Passive devices 400 may further include a third passive device 430, which is disposed in the third trench TR3, between the third bumps 330 and the substrate 100. The third passive device 430 may be disposed between the semiconductor chip 200 and the substrate 100 through an upper solder layer 330b.

According to some example embodiments, passive devices can be disposed not only in edge areas, but also in other areas of a semiconductor chip, for example, a central area of the semiconductor chip. In some example embodiments, stress that may be caused by the difference in CTE between a substrate and the semiconductor chip can be further reduced via bumps between the semiconductor chip and the passive devices.

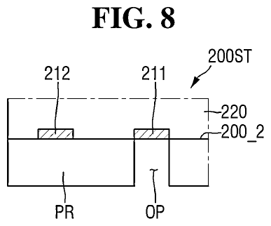

FIGS. 8 through 16 are cross-sectional views illustrating a method of fabricating a semiconductor package according to some example embodiments of the inventive concepts. Specifically, FIGS. 8 through 16 illustrate a method of fabricating the semiconductor package 1000A of FIG. 2. The example embodiment of FIGS. 8 through 16 will hereinafter be described, focusing mainly on the differences with the embodiment of FIGS. 1 through 3.

Referring to FIGS. 8 through 11, a semiconductor chip structure 200ST, in which a bump structure 300 is disposed, may be formed in part of a semiconductor chip 200.

Referring to FIG. 8, photoresist PR may be formed on a bottom surface 200_2 of the semiconductor chip 200, on which first semiconductor chip pads 211 and second semiconductor chip pads 212 are formed. The photoresist PR may be formed to selectively expose the first semiconductor chip pads 211 via an opening OP, on which a pillar layer 310a is to be formed. Although not specifically illustrated, a passivation layer may be disposed on the bottom surface 200_2 of the semiconductor chip 200, and an under bump metal layer may be further disposed on the first semiconductor chip pads 211 and the second semiconductor chip pads 212.

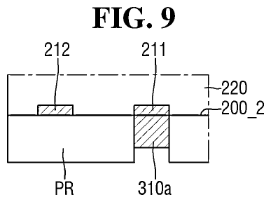

Referring to FIG. 9, the pillar layer 310a may be formed on the first semiconductor chip pads 211 and the second semiconductor chip pads 212, via Cu electroplating. In some example embodiments, the pillar layer 310a may be formed to be thinner than the photoresist PR.

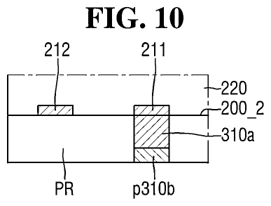

Referring to FIG. 10, a first upper metal layer p310b may be formed on the pillar layer 310a via solder electroplating.

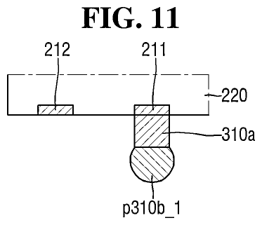

Referring to FIG. 11, the bottom surface 200_2 of the semiconductor layer 200, the first semiconductor chip pads 211, and the second semiconductor chip pads 212 may be exposed by removing the photoresist PR and the under bump metal layer. Thereafter, a first upper solder layer p310b_1 may be formed on the pillar layer 310a via a reflow process.

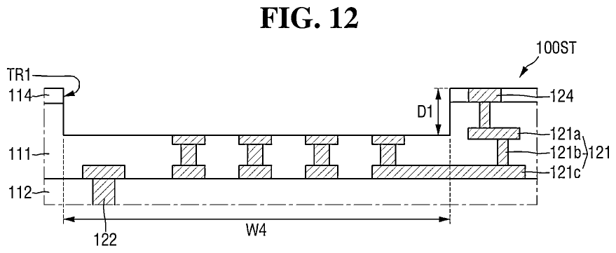

Referring to FIGS. 12 through 14, a substrate structure 100ST, in which a first passive device 410 is received, may be formed.

Referring to FIG. 12, a substrate 100, in which a trench TR1 is formed, may be provided, and the trench TR1 may be disposed in a region where the first passive device 410 is to be disposed. The trench TR1 may have a bottom surface exposing at least part of a first wiring layer 121. The trench TR1 may be formed to have a first depth D1 in a fourth direction DR4 and a fourth width W4 in a third direction DR3.

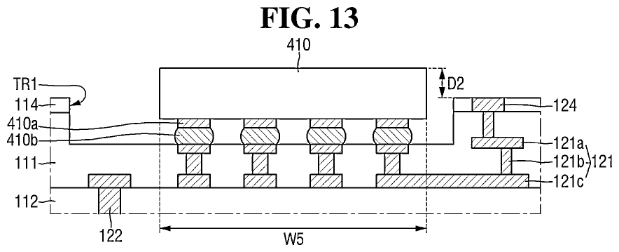

Referring to FIG. 13, the first passive device 410 may be attached to the inside of the trench TR1 such that the bottom surface of the trench TR1 may face the top surface of the first passive device 410. The first passive device 410 may be received on the bottom surface of the trench TR1 through a lower pillar layer 410a and a lower solder layer 410b.

The top surface of the first passive device 410 may protrude from the top surface of the substrate 100 by as much as a second height D2. The first passive device 410 may be formed to have a fifth width W5 in the third direction DR3. The fifth width W5 of the first passive device 410 may be less than the fourth width W4 of the trench TR1.

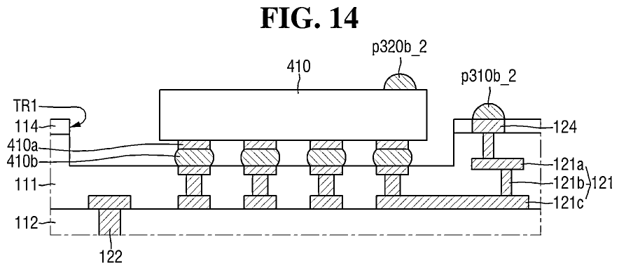

Referring to FIG. 14, an upper metal layer may be formed on the top surface of the first passive device 410 and on first pads 124 of the substrate 100. Thereafter, a second upper solder layer p320b_2 may be formed on the top surface of the first passive device 410, and a third upper solder layer p310b_2 may be formed on the first pads 124.

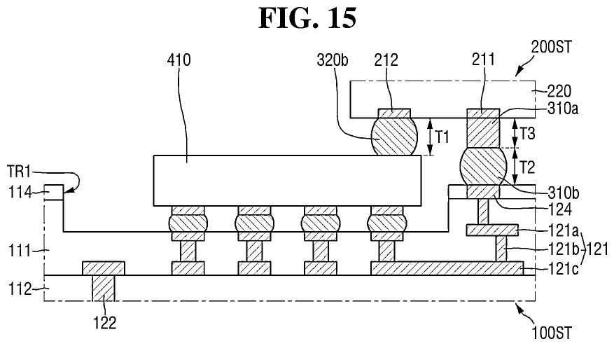

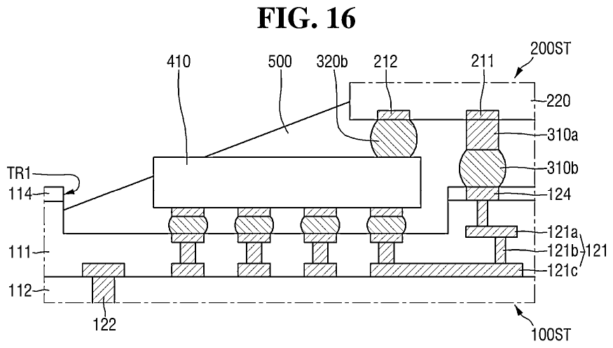

Referring to FIGS. 15 and 16, the substrate structure 100ST and the semiconductor chip structure 200ST may be bonded.

Specifically, the substrate structure 100ST and the semiconductor chip structure 200ST may be arranged such that the top surface of the substrate 100 and the bottom surface of the semiconductor chip 200 may face each other.

Thereafter, referring to FIG. 15, the second upper solder layer p320b_2, which is formed on the top surface of the first passive device 410, and the second semiconductor chip pads 212 may be bonded, thereby forming second bumps 320, and the third upper solder layer p310b_2, which is formed on the first pads 124 of the substrate 100, and the first upper solder layer p310b_1, which is on the bottom surface 200_2 of the semiconductor chip 200, may be bonded, thereby forming first bumps 310.

A thickness T1 of the second bumps 320 may differ from the thickness, in the fourth direction DR4, of the first bumps 310 (e.g., the sum of T2 and T3).

Referring to FIG. 16, an underfill material 500 may be filled between the semiconductor chip 200 and the substrate 100.

In this manner, the semiconductor package 1000A of FIG. 2 may be obtained.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

Some example embodiments of the inventive concepts have been described above with reference to the accompanying drawings, but the inventive concepts are not limited thereto and may be implemented in various different forms. It will be understood that the inventive concepts can be implemented in other specific forms. Therefore, it should be understood that the example embodiments set forth herein are illustrative in all respects and not limiting.

What is claimed is:

1. A semiconductor package comprising:
a semiconductor chip including a first area and a second area around the first area;
a substrate including a second surface, the second surface facing a first surface of the semiconductor chip, a first trench defined on the second surface, and the first trench at least partially overlapping the second area of the semiconductor chip;
a bump structure including first bumps on the first area of the semiconductor chip, and second bumps on the second area of the semiconductor chip, the bump structure between the substrate and the semiconductor chip; and
a first passive device in the first trench,
wherein the second bumps are in contact with the first surface of the semiconductor chip and the first passive device.

2. The semiconductor package of claim 1, wherein
each of the first bumps includes a first upper pillar layer on the first surface of the semiconductor chip, and a first upper solder layer, between the first upper pillar layer and the second surface of the substrate, and
each of the second bumps includes a second upper solder layer on the first surface of the semiconductor chip.

3. The semiconductor package of claim 2, wherein
the second upper solder layer is between a top surface of the first passive device and the first surface of the semiconductor chip, and
the first upper solder layer is between the second surface of the substrate and the first surface of the semiconductor chip.

4. The semiconductor package of claim 1, wherein
the first passive device is in the first trench, the first trench having a first depth from the second surface of the substrate, and
a top surface of the first passive device protrudes from the second surface of the substrate by a second height.

5. The semiconductor package of claim 1, wherein a thickness of the second bumps differs from a thickness of the first bumps.

6. The semiconductor package of claim 1, wherein
the substrate includes an insulating layer and a wiring layer, the wiring layer electrically connected to the semiconductor chip, and
the first passive device and the semiconductor chip are electrically connected through the first bumps and the wiring layer.

7. The semiconductor package of claim 1, wherein the first passive device and the semiconductor chip are not electrically connected through the second bumps.

8. The semiconductor package of claim 1, wherein
the semiconductor chip includes a third area on an inside of the first area,
a second trench, which overlaps with the third area of the semiconductor chip, is defined in the substrate,
the bump structure includes third bumps on the third area of the semiconductor chip, the third bumps between the substrate and the semiconductor chip, and
the semiconductor package further comprises a second passive device in the second trench, the second passive device between the third bumps and the substrate.

9. The semiconductor package of claim 1, wherein
the first passive device is on the substrate, and
the first passive device is spaced apart from the substrate by a lower pillar layer and a lower solder layer between a bottom surface of the first passive device and the substrate.

10. The semiconductor package of claim 1, wherein
the first passive device is on the substrate, and
a lower solder layer is between a bottom surface of the first passive device and the substrate.

11. The semiconductor package of claim 1, further comprising:
an underfill material between the semiconductor chip and the substrate, the underfill material filling at least part of the first trench.

12. A semiconductor package comprising:
a semiconductor chip including a first area and a second area, the second area around the first area in a plan view of the semiconductor chip;
a substrate including a top surface, the top surface facing a bottom surface of the semiconductor chip, a trench defined in the top surface, and the trench at least partially overlapping the second area of the semiconductor chip;
a bump structure including connection bumps in the first area of the semiconductor chip, and dummy bumps on the second area of the semiconductor chip, the bump structure between the substrate and the semiconductor chip; and
a passive device in the trench, the passive device between the bump structure and the substrate,
wherein a thickness of the dummy bumps differs from a thickness of the connection bumps, the dummy bumps are in contact with the passive device, and the connection bumps are in contact with the substrate.

13. The semiconductor package of claim 12, wherein the passive device is electrically connected to the semiconductor chip through the connection bumps.

14. The semiconductor package of claim 12, wherein
each of the connection bumps includes a first upper pillar layer on the bottom surface of the semiconductor chip, and a first upper solder layer between the first upper pillar layer and the top surface of the substrate, and
each of the dummy bumps includes a second upper solder layer on the bottom surface of the semiconductor chip.

15. The semiconductor package of claim 14, wherein
the second upper solder layer is between a top surface of the passive device and the bottom surface of the semiconductor chip, and
the first upper solder layer is between the top surface of the substrate and the bottom surface of the semiconductor chip.

16. The semiconductor package of claim 14, wherein a thickness of the second upper solder layer differs from a thickness of the first upper solder layer.

17. The semiconductor package of claim 16, wherein the thickness of the second upper solder layer is less than a sum of the thickness of the first upper solder layer and a thickness of the first upper pillar layer.

18. The semiconductor package of claim 12, wherein
in a plan view of the semiconductor chip, the semiconductor chip includes a third area on an inside of the first area, and
the passive device is in the third area.

19. A method of fabricating a semiconductor package, the method comprising:
providing a semiconductor chip including a first area and a second area, a first semiconductor chip pad in the first area, and a second semiconductor chip pad in the second area;
forming photoresist on a bottom surface of the semiconductor chip, the photoresist including an opening which exposes the first semiconductor chip pad;
forming first and second metal material layers in the opening;
removing the photoresist;
providing a substrate including a trench, the trench including a bottom surface which exposes at least one wiring layer;
forming a passive device in the trench, the passive device including a bottom surface that faces the bottom surface of the trench;
forming a third metal material layer on the wiring layer and a fourth metal material layer on a top surface of the passive device;
arranging the substrate and the semiconductor chip where the top surface of the substrate faces the bottom surface of the semiconductor chip;
bonding the second metal material layer and the third metal material layer; and
bonding the second semiconductor chip pad and the fourth metal material layer.

20. The method of claim 19, wherein forming the passive device in the trench comprises forming the passive device with the top surface of the passive device protruding beyond the top surface of the substrate.
